(19) United States
(12) Patent Application Publication
(10) Pub. No.: US 2014/0339509 A1
(43) Pub. Date: Nov. 20, 2014

(54) ORGANIC LIGHT-EMITTING DISPLAY APPARATUS

(71) Applicant: Samsung Display Co., Ltd., Yongin-City (KR)

(72) Inventors: Hae-Yun Choi, Yongin-City (KR); Won-Sang Park, Yongin-City (KR); Jae-Ik Lim, Yongin-City (KR)

(73) Assignee: Samsung Display Co., Ltd., Yongin-City (KR)

(21) Appl. No.: 14/011,990

(22) Filed: Aug. 28, 2013

(30) Foreign Application Priority Data
May 16, 2013 (KR) 10-2013-0056049

(51) Int. Cl. H01L 27/32; H01L 51/52

(52) U.S. Cl. CPC H01L 27/3211; H01L 51/5275
USPC 257/40

(57) ABSTRACT

Provided is an organic light-emitting display apparatus that includes an organic light-emitting device that includes a plurality of sub-pixels that emit different light colors; an encapsulating film formed on the organic light-emitting device; a lens layer that is formed on the encapsulating film and includes convex surfaces that are disposed on regions corresponding to the sub-pixels and protrude in a light emission direction and a direction opposite to the light emission direction; and an anti-reflection film that is formed on the lens layer to prevent reflection of external light and includes color filters on regions corresponding to each of the sub-pixels.

This application claims priority to Korean Patent Application No. 10-2013-0056049, filed on May 16, 2013, and all the benefits accruing therefrom under 35 U.S.C. §119, the disclosure of which is incorporated herein in its entirety by reference.

### BACKGROUND

1. Field

The invention relates to an organic light-emitting display apparatus.

2. Description of the Related Art

An organic light-emitting display apparatus is a self-emissive type display apparatus that does not require an additional light source, is able to be operated at a relatively low voltage, can be configured as a lightweight and thin film type, and has high quality characteristics such as wide viewing angles, high contrast and short response times, and thus, draws attention as a next generation display apparatus.

An organic light-emitting display apparatus realizes a full-color by using color light, such as three lights of red, green and blue colors. In order to realize a high-quality color image regardless of a user's viewing angle, there is a need to develop an organic light-emitting display apparatus having a high optical efficiency and a large lateral viewing angle.

### SUMMARY

One or more exemplary embodiment of the invention provides a structure of an organic light-emitting display apparatus.

According to an exemplary embodiment of the invention, there is provided an organic light-emitting display apparatus including: an organic light-emitting device layer including: a plurality of sub-pixels which emits lights of different colors, and an organic light-emitting device in each sub-pixel; an encapsulating film on the organic light-emitting device layer; a lens layer on the encapsulating film and including: a lens unit corresponding to the each sub-pixel and including facing convex surfaces respectively protruding in a light emission direction, and a direction opposite to the light emission direction; and an anti-anti-reflection film on the lens layer and including a color filter corresponding to the each sub-pixel.

The anti-reflection film may further include a light blocking unit between neighboring sub-pixels.

The plurality of sub-pixels is arranged in a direction, and the light blocking unit may be separated from the convex surface protruding in the light emission direction among the convex surfaces of the lens unit, by a predetermined gap along the direction in which the plurality of sub-pixels is arranged.

The convex surface protruding in the light emission direction among the convex surfaces of the lens unit has a width smaller than that of the convex surface protruding in a direction opposite to the light emission direction, the widths taken in the direction in which the plurality of sub-pixels is arranged.

The lens layer may further include: a first lens sub-layer on the encapsulating film and having a first refractive index; and a second lens sub-layer on the first lens sub-layer, having a second refractive index. The second lens sub-layer may include a first convex surface protruding in the light emission direction among the convex surfaces of the lens unit, and a second convex surface protruding in the direction opposite to the light emission direction among the convex surfaces of the lens unit. A first surface of the first lens sub-layer may contact the second lens sub-layer and include a concave surface corresponding to the second convex surface of the second lens sub-layer.

The second refractive index may be greater than the first refractive index.

The first refractive index may be about 1.3 or less, and the second refractive index may be in a range from about 1.7 to about 1.9.

An imaginary surface may extend in a direction in which the plurality of sub-pixels is arranged. A first inclination angle formed by the first convex surface at an edge of the first convex surface, with respect to the imaginary surface, may be smaller than a second inclination angle formed by the second convex surface at an edge of the second convex surface, with respect to the imaginary surface.

The first inclination angle may be in a range from about 15° to about 25°.

The second inclination angle may be in a range from about 30° to about 40°.

The convex surface protruding in the direction opposite to the light emission direction among the convex surfaces of the lens unit, may include: curved convex surfaces respectively protruding from opposing edges of the convex surface, and a flat surface between the curved convex surfaces.

According to another exemplary embodiment of the invention, there is provided an organic light-emitting display apparatus including: an organic light-emitting device layer including: a plurality of sub-pixels which emits red, green and blue light, and an organic light-emitting device in each sub-pixel; an encapsulating film on the organic light-emitting device layer; a lens layer on the encapsulating film and including: a first convex surface corresponding to each sub-pixel and protruding in a light emission direction, and a second convex surface facing the first convex surface and protruding in a direction opposite to the light emission direction; and an anti-reflection film on the lens layer.

The lens layer may further include: a first lens sub-layer on the encapsulating film and having a low refractive index; and a second lens sub-layer on the first lens sub-layer and having a high refractive index. The second lens sub-layer may include the first convex surface protruding in the light emission direction and the second convex surface protruding in the direction opposite to the light emission direction.

A first surface of the first lens sub-layer may contact the second lens sub-layer may and include a concave surface corresponding to the second convex surface of the second lens sub-layer.

The second convex surface may include curved convex surfaces respectively protruding from opposing edges of the second convex surface, and a flat surface between the curved convex surface and corresponding to a central region of the each sub-pixel.

The anti-reflection film may include: a color filter corresponding to each of the sub-pixels; and a light blocking unit between the sub-pixels.

The plurality of sub-pixels may be arranged in a direction, and the first convex surface may be separated from the light blocking unit along the direction in which the sub-pixels is arranged.

An imaginary surface may extend in a direction in which the plurality of sub-pixels is arranged, and a first inclination angle formed by the first convex surface at an edge of the first convex surface, with respect to the imaginary surface, may have a value different from that of a second inclination angle formed by the second convex surface at an edge of the second convex surface, with respect to the imaginary surface.

The first inclination angle may be smaller than the second inclination angle.

The first inclination angle may be in a range from about 15° to about 25°, and the second inclination angle may be in a range from about 30° to about 40°.

According to one or more exemplary embodiment of the invention, an organic light-emitting display apparatus having a high front brightness and a large lateral viewing angle is provided.

Also, the organic light-emitting display apparatus includes an anti-reflection film that includes color filters and light blocking layers, and a lens layer having a relatively small thickness is on a thin film encapsulating layer, and thus, the organic light-emitting display apparatus may have a high resistance to bending.

### BRIEF DESCRIPTION OF THE DRAWINGS

The above and other features and advantages of the invention will become more apparent by describing in detail exemplary embodiments thereof with reference to the attached drawings in which:

FIG. 1 is a schematic cross-sectional view illustrating an exemplary embodiment of an organic light-emitting display apparatus according to the invention;

FIG. 2 is an enlarged view of region II of FIG. 1; and

FIG. 3 is a cross-sectional view of an exemplary embodiment of a single sub-pixel region of the organic light-emitting display apparatus of FIG. 1;

FIG. 4 is a schematic cross-sectional view illustrating another exemplary embodiment of an organic light-emitting display apparatus according to the invention;

FIG. 5 is an enlarged view of region V of FIG. 4;

FIG. 6 is a schematic cross-sectional view illustrating an organic light-emitting display apparatus according to a comparative example;

FIG. 7A is a simulation image showing intensity of light emitted from a single pixel of the exemplary embodiment of the organic light-emitting display apparatus described with reference to FIGS. 1 and 2, according to the invention; and

FIG. 7B is a simulation image showing intensity of light emitted from a single pixel of the comparative example of the organic light-emitting display apparatus described with reference to FIG. 6.

### DETAILED DESCRIPTION

While exemplary embodiments are capable of various modifications and alternative forms, embodiments thereof are shown by way of example in the drawings and will herein be described in detail. It should be understood, however, that there is no intent to limit exemplary embodiments to the particular forms disclosed, but on the contrary, exemplary embodiments are to cover all modifications, equivalents, and alternatives falling within the scope of the invention. In describing the invention, when practical descriptions with respect to related known function and configuration may unnecessarily make unclear of the scope of the invention, the descriptions thereof will be omitted.

It will be understood that, although the terms “first”, “second”, etc. may be used herein to describe various elements, these elements should not be limited by these terms. These terms are only used to distinguish one element from another. The terminologies used herein are for the purpose of describing embodiments only and are not intended to be limiting of exemplary embodiments.

As used herein, the singular forms “a,” “an,” and “the” are intended to include the plural forms as well, unless the context clearly indicates otherwise. It will be further understood that the terms “comprises,” “comprising,” “includes,” and/or “including” when used herein, specify the presence of stated features, integers, steps, operations, elements, and/or components, but do not preclude the presence or addition of one or more other features, integers, steps, operations, elements, components, and/or groups thereof. As used herein, the symbol “/” may be interpreted as “and” or “or” according to the circumstance.

In the drawings, thicknesses may be exaggerated for clarity of layers and regions. Like reference numerals are used to like elements throughout the specification. When a layer, a film, a region or a panel is referred to as being “on” another element, it can be directly on the other layer or substrate, or intervening layers may also be present.

Spatially relative terms, such as “lower,” “upper” and the like, may be used herein for ease of description to describe the relationship of one element or feature to another element(s) or feature(s) as illustrated in the figures. It will be understood that the spatially relative terms are intended to encompass different orientations of the device in use or operation, in addition to the orientation depicted in the figures. For example, if the device in the figures is turned over, elements described as “lower” relative to other elements or features would then be oriented “above” relative to the other elements or features. Thus, the exemplary term “lower” can encompass both an orientation of above and below. The device may be otherwise oriented (rotated 90 degrees or at other orientations) and the spatially relative descriptors used herein interpreted accordingly.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10%, 5% of the stated value.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, the invention will be described in detail with reference to the accompanying drawings.

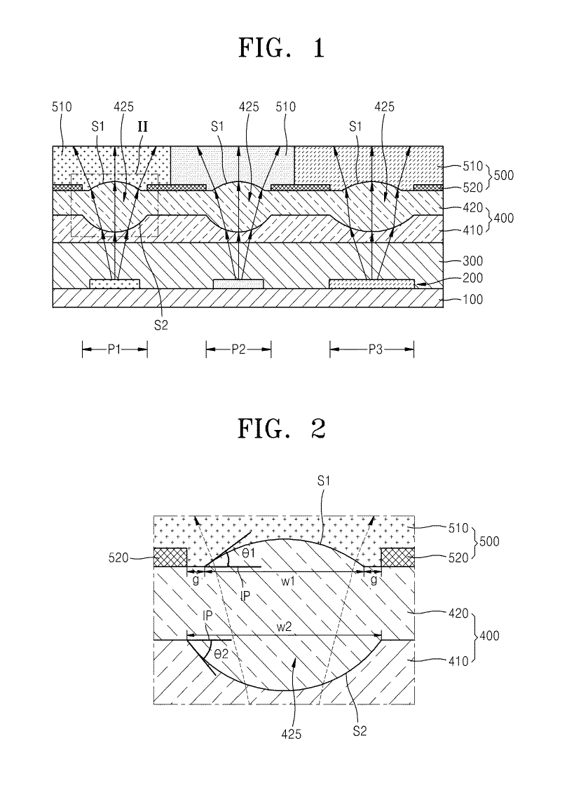

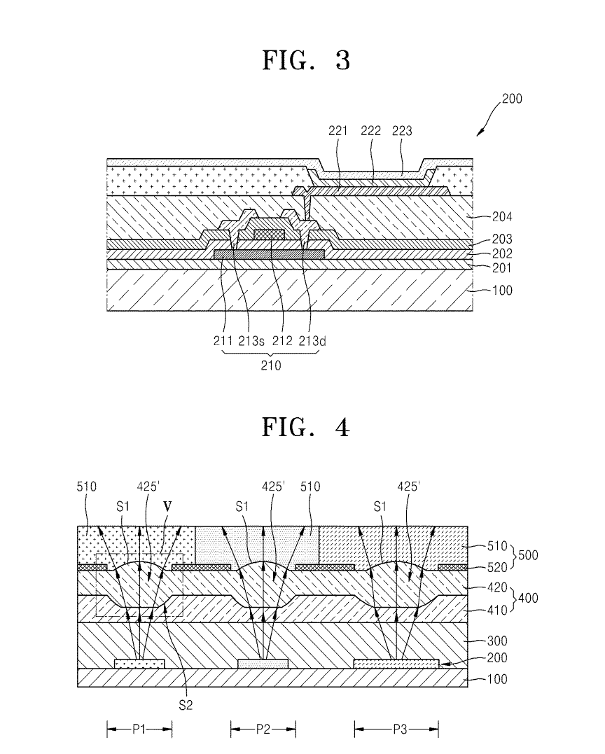

FIG. 1 is a schematic cross-sectional view illustrating an exemplary embodiment of an organic light-emitting display apparatus according to the invention. FIG. 2 is an enlarged view of region II of FIG. 1. FIG. 3 is a cross-sectional view of an exemplary embodiment of a single sub-pixel region of the organic light-emitting display apparatus of FIG. 1.

Referring to FIG. 1, the organic light-emitting display apparatus may include a substrate 100, an organic light-emitting device layer including one or more organic light-emitting device 200 disposed on the substrate 100, an encapsulating film 300, a lens layer 400, and an anti-reflection film 500.

The substrate 100 may include a plastic having a high thermal resistance and durability. However, the substrate 100 according to the invention is not limited thereto, and the substrate 100 may include various materials, such as a metal or glass.

The organic light-emitting device 200 is disposed on the substrate 100. The organic light-emitting device layer including a plurality of organic light-emitting devices 200 may include a plurality of sub-pixels P1, P2 and P3 defined therein that emits light of different colors. In one exemplary embodiment, for example, the organic light-emitting device layer may include a plurality of first sub-pixels P1 that emit red light, a plurality of second sub-pixels P2 that emit green light, and a plurality of third sub-pixels P3 that emit blue light.

Referring to FIG. 3, the organic light-emitting device 200 may include a buffer layer 201 that is on the substrate 100 to block penetration of foreign materials and moisture to a remainder of the organic light-emitting device 200, a thin film transistor 210 on the buffer layer 201, a first electrode 221 connected to the thin film transistor 210, a second electrode 223 that faces the first electrode 221, and an intermediate layer 222 that is disposed between the first and second electrodes 221 and 223 and includes an organic light-emitting layer.

The thin film transistor 210 may include an active layer 211, a gate electrode 212, a source electrode 213s and a drain electrode 213d. A first insulating layer 202 may be interposed between the gate electrode 212 and the active layer 211 as a gate insulating layer to insulate the gate electrode 212 and the active layer 211 from each other. The active layer 211 may include a channel region disposed in the middle of the active layer 211, and a source region and a drain region that are respectively disposed on both sides of the channel region. The active layer 211 may include amorphous silicon, crystalline silicon or semiconductor oxide, but not being limited thereto.

In an exemplary embodiment of manufacturing the organic light-emitting device 200, the source region and the drain region respectively disposed at opposing edges of the channel region may be formed (e.g., provided) by doping a high concentration dopant by using a gate electrode 212 as a self-aligned mask. In FIG. 3, a top gate type thin film transistor 210 is depicted. However, the thin film transistor according to the invention is not limited thereto, and as another exemplary embodiment of the invention, a bottom gate type thin film transistor may be employed.

The source electrode 213s and the drain electrode 213d are disposed on the gate electrode 212, and a second insulating layer 203 therebetween. The source electrode 213s and the drain electrode 213d are physically and/or electrically connected to the source region and the drain region of the active layer 211, respectively. A third insulating layer 204 may be disposed on the source electrode 213s and the drain electrode 213d.

One of the source electrode 213s and the drain electrode 213d may be physically and/or electrically connected to the first electrode 221. The intermediate layer 222 which includes the organic light-emitting layer, and the second electrode 223, may be disposed on the first electrode 221.

The structure depicted in FIG. 3 is included in each of the sub-pixels P1, P2 and P3, and the organic light-emitting layer included in the intermediate layer 222 of each of the first, second, and third sub-pixels P1, P2 and P3 includes an organic material that emits a color light such as red, green and blue color light. The organic light-emitting layer that emits red, green and blue color light may include a low or high molecule organic material. The organic light-emitting layer, the intermediate layer 222 may further include at least one of a hole transport layer, a hole injection layer, an electron transport layer or an electron injection layer.

Referring again to FIG. 1, the encapsulating film 300 is disposed on the organic light-emitting device 200 to reduce or effectively prevent penetration of foreign materials and/or external agents into the organic light-emitting device 200. In an exemplary embodiment, the encapsulating film 300 may be directly on the organic light-emitting device 200, but not being limited thereto or thereby. In an exemplary embodiment of manufacturing the organic light-emitting display apparatus, the encapsulating film 300 may be an encapsulating thin film that is formed (e.g., provided) by alternately stacking an organic layer and an inorganic layer. The organic layer may include an acryl based resin, an epoxy based resin or a polymer based material such as polyimide and polyethylene, or a combination of these materials. The inorganic layer may include a metal oxide, a metal nitride, a metal carbonate or a combination of these materials.

The lens layer 400 may be disposed on the encapsulating film 300. In an exemplary embodiment, the lens layer 400 may be directly on a whole surface of the encapsulating film 300, but not being limited thereto or thereby. The lens layer 400 may include a lens unit 425 on a region of the organic light-emitting display apparatus corresponding to each of the sub-pixels P1, P2 and P3.

The anti-reflection film 500 is disposed on the lens layer 400 to reduce or effectively prevent external light reflection. The anti-reflection film 500 may include one or more color filter 510 at regions corresponding to the sub-pixels P1, P2 and P3, and a light blocking unit 520 between adjacent color filters 510 (or regions between the sub-pixels P1, P2 and P3). Since a small amount of light that enters into the color filters 510 is reflected, an external light visibility is increased and an image definition may be increased. The light blocking units 520 disposed on the regions, that is, non-emission regions between the sub-pixels P1, P2 and P3 reduce contrast caused by lower reflection of external light, and may include a black matrix that absorbs the wavelength of a visible light region. Here, the lower reflection indicates the reflection of external light by an electrode or a wire of the organic light-emitting device 200 and/or the substrate 100 that are under the anti-reflection film 500.

The lens unit 425 included in the lens layer 400 may be a biconvex lens. In one exemplary embodiment, for example, the lens unit 425 may include a first convex surface S1 that protrudes in an emission direction (hereinafter, a first direction) of light emitted from the organic light-emitting device 200, and a second convex surface S2 that protrudes in a direction opposite (hereinafter, a second direction) to the emission direction of light.

The lens layer 400 includes flat regions (e.g., non-emission regions) between the neighboring sub-pixels P1, P2 and P3, and corrugate regions disposed on regions corresponding to the sub-pixels P1, P2, and P3. Here, the corrugate surface corresponds to the convex surfaces of the lens unit 425. In one exemplary embodiment, for example, the lens unit 425 may be defined by at least one of the plural layers that form the lens layer 400 that includes a corrugate surface.

According to the illustrated embodiment, the lens layer 400 may include a first lens sub-layer 410 disposed on the encapsulating film 300 and a second lens sub-layer 420 disposed on the first lens sub-layer 410. Here, the second lens sub-layer 420 may form the lens unit 425 by including convex portions that protrude in the first and second directions from a substantially planar main portion. A first surface of the first lens sub-layer 410, that is, an upper surface that contacts the second lens sub-layer 420, may include a concave recess having a shape corresponding to a convex surface of the second lens sub-layer 420 that protrudes in the second direction.

Referring again to FIG. 1, light from the organic light-emitting device 200 is emitted in all directions. Here, the lens unit 425 collects light incident to regions outside the sub-pixels P1, P2 and P3, that is, non-emission regions and emits the collected light to outside the organic light-emitting device 200. That is, the second lens sub-layer 420 includes the lens unit 425 to collect light that is subsequently emitted in substantially all directions, and thus, the brightness of a front surface and lateral viewing angles of the organic light-emitting device 200 may be increased. The brightness of the front surface of the organic light-emitting device 200 may further be increased by the first lens sub-layer 410 including a material having a relatively low refractive index and the second lens sub-layer 420 including a material having a relatively high refractive index.

The first lens sub-layer 410 may include an organic material having the relatively low refractive index, and the second lens sub-layer 420 may include an organic material having the relatively high refractive index. Alternatively, the first lens sub-layer 410 may include an inorganic material having the relatively low refractive index, and the second lens sub-layer 420 may include an inorganic material having the relatively high refractive index. In one exemplary embodiment, for example, the first lens sub-layer 410 may include an organic material or an inorganic material having a refractive index of about 1.3 or less, and the second lens sub-layer 420 may include an organic material or an inorganic material having a refractive index in a range from about 1.7 to about 1.9.

The organic material having a low refractive index may include at least one selected from an acryl based resin such as acrylic and acrylates, a polyacryl based resin, a polyimide based resin, an epoxy resin and a melanin resin, and a combination thereof. The organic material having a high refractive index may include at least one selected from a polysiloxane based resin, a polyacryl based resin, a polyimide based resin, an epoxy region and an acryl group resin, and a combination thereof. The inorganic material having a low refractive index may include at least one selected from a silicon based resin, and an inorganic material such as a siloxane based, a dimethylsiloxane based, and a phenyltrichlorosilane based material, and a combination thereof. The inorganic material having a high refractive index may include at least one selected from a silicon group resin, and an inorganic material such as a siloxane based, a dimethylsiloxane based and a phenyltrichlorosilane based material, and a combination thereof.

The first convex surface S1 and the second convex surface S2 of the lens unit 425 may have different widths taken in a direction parallel with the substrate 100. Referring to FIG. 2, a width w1 of the first convex surface S1 may be smaller than a width w2 of the second convex surface S2. In view of the direction which is an arranging direction (hereinafter, a width direction) of the sub-pixels P1, P2 and P3, the light blocking units 520 are disposed on opposing sides of the first convex surface S1 and separated from opposing edges of the first convex surface S1. An edge of the first convex surface S1 is separated by a predetermined gap g taken in the arranging direction from a respective light blocking unit 520.

Light from the organic light-emitting device 200 is refracted by the second convex surface S2 formed by the second lens sub-layer 420 having a high refractive index, after passing through the first lens sub-layer 410, and afterwards, is emitted through the first convex surface S1, as illustrated by the arrowed-lines in FIG. 1. If the opposing edges of the first convex surface S1 contact the light blocking units 520, respectively, all of the light emitted through the edges of the first convex surface S1, for example, the opposing edges of the first convex surface S1 may be absorbed by the light blocking units 520, and thus, the optical efficiency of the organic light-emitting device 200 may be greatly reduced. However, in the lens unit 425 according to the illustrated embodiment, both of the opposing edges of the first convex surface S1 that protrudes in the first direction are separated from the light blocking units 520 in the arranging direction, and thus, the absorption of light that is emitted through the lens unit 425 by the light blocking units 520 may be reduced or effectively be prevented.

At edges of the lens unit 425, for example, at opposing ends of the lens unit 425, the first and second convex surfaces S1 and S2 form a predetermined angle with respect to an imaginary surface IP that extends along the width direction of the lens unit 425. That is, at the edge of the first convex surface S1, the first convex surface S1 of the lens unit 425 forms a first inclination angle θ1 with respect to the imaginary surface IP 1, and at the edge of the second convex surface S2, the second convex surface S2 of the lens unit 425 forms a second inclination angle θ2 with respect to the imaginary surface IP. Through the structure of the lens unit 425 that has the first and second inclination angles θ1 and θ2, a lateral viewing angle of light emitted from the organic light-emitting device 200 may be ensured.

As an exemplary embodiment of the invention, the first inclination angle θ1 that is formed by the first convex surface S1 with respect to the imaginary surface IP that extends along the width direction of the lens unit 425 may have a different value from a value of the second inclination angle θ2 that is formed by the second convex surface S2 with respect to the imaginary surface IP at the edge of the second convex surface S2. As described above, the lens unit 425 collects light emitted towards front side from the organic light-emitting device 200. Furthermore, since the light blocking units 520 are disposed on both edges of the lens unit 425 light, it is desirable to increase collecting efficiency of the light and to reduce or effectively prevent light passed through the lens unit 425 from being absorbed by the light blocking units 520.

For this, the first inclination angle θ1 is smaller than the second inclination angle θ2, that is, the second inclination angle θ2 may be greater than the first inclination angle θ1. In one exemplary embodiment, for example, the second inclination angle θ2 may be in a range from about 30 degrees (°) to about 40°, and the first inclination angle θ1 may be in a range from about 15° to about 25°. If the second inclination angle θ2 exceeds or is outside the above range, the intensity of light collected may be reduced, and most of the light passed through the lens unit 425 may be absorbed by the light blocking units 520. If the first inclination angle θ1 exceeds or is outside the above range, most of the light passed through the edges of the first convex surface S1 may be absorbed by the light blocking units 520.

According to the illustrated embodiment, a size of the lens unit 425 included in the sub-pixel P3 that emits blue light may be greater than that of the lens unit 425 included in the sub-pixels P2 and P3 that emit color light other than the blue light. Blue light emitted from the organic light-emitting device 200 has a relatively lower brightness and light emission efficiency than red and green lights. Therefore, the size of the lens unit 425 included in the sub-pixel P3 that emits blue light may be greater than that of the lens unit 425 included in the sub-pixels P2 and P3 that emit red and green lights, and the light collecting efficiency of blue light may be increased. The size of the lens unit 425 may refer to the width of the pixel taken in the arranging direction, such as being in the same direction as the widths w1 and w2 of the convex surfaces S1 and S2.

In FIG. 1, a single lens unit 425 is included in each of the sub-pixels P1, P2 and P3, but the invention is not limited thereto. As another exemplary embodiment of the invention, a plurality of lens units 425 may be disposed in each of the sub-pixels P1, P2 and P3. Where the plurality of lens units 425 is disposed in each of the sub-pixels P1, P2 and P3, the conditions of widths and inclination angles with respect to the first convex surface S1 and the second convex surface S2 of each of the lens units 425 are the same as the conditions described above. Also, edges or boundaries of the convex surfaces that protrude in the first direction of the lens units 425 are separated from the light blocking units 520.

As described above, through the lens unit 425, the light blocking units 520 disposed separated from opposing edges of the lens unit 425, and the anti-reflection film 500 having color filters 510, the reflection of external light is suppressed, lateral viewing angles are ensured, and a color shift of lateral viewing angles is reduced or effectively prevented, thereby increasing image quality.

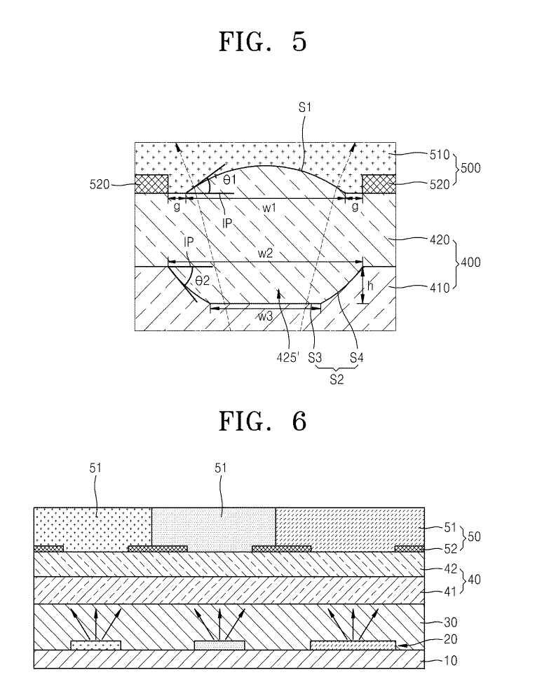

FIG. 4 is a schematic cross-sectional view illustrating another exemplary embodiment of an organic light-emitting display apparatus according to the invention. FIG. 5 is an enlarged view of region V of FIG. 4.

Referring to FIGS. 4 and 5, the organic light-emitting display apparatus according to the illustrated embodiment is different from the organic light-emitting display apparatus described with reference to FIGS. 1 and 2 in that a lens unit 425′ has a different shape from that of the lens unit 425.

Referring to FIGS. 4 and 5, the lens unit 425′ includes a first convex surface S1 that protrudes in a first direction and a second convex surface S2 that protrudes in a second direction from a substantially planar main portion. However, a central region of the second convex surface S2 may include a flat surface S3. In the exemplary embodiment described with reference to FIGS. 1 and 2, both surfaces, that is, the first and second convex surfaces S1 and S2 of the lens unit 425 are entirely curved surfaces. However, according to the illustrated exemplary embodiment, the first convex surface S1 of the lens unit 425′ is an entirely curved surface, and the second convex surface S2 may include the flat surface S3.

Light emitted from the central region of each of the sub-pixels P1, P2 and P3 of the organic light-emitting device 200 has a high intensity, and thus, the second convex surface S2 includes the flat surface S3 in the center region and a curved surface S4 on an edge region, so that a region corresponding to the center of the sub-pixel directly transmits light generated from the organic light-emitting device 200 and the edge region collects light.

A total width w2 of the second convex surface S2 is in a range from about 7 micrometers (μm) to about 13 μm, a width w3 of the flat surface S3 may be in a range from about 2 μm to about 6 μm, and a height h of the second convex surface S2 taken from the flat region of the lens layer 400 may be in a range from about 0.5 μm to about 3.5 μm. However, when the lens unit 425′ is included in the sub-pixel P3 emits a blue light, in order to increase an efficiency of blue light, the total width w2 of the second convex surface S2 may be in a range from about 17 μm to about 23 μm, and the width w3 of the flat surface S3 may be in a range from about 8 μm to about 12 μm.

In the illustrated exemplary embodiment, the first inclination angle θ1 may be in a range from about 15° to about 25°, and the second inclination angle θ2 may be in a range from about 30° to about 40°. Also, similar to the exemplary embodiment described with reference to FIGS. 1 and 2, the total width w2 of the second convex surface S2 is greater than the total width w1 of the first convex surface S1.

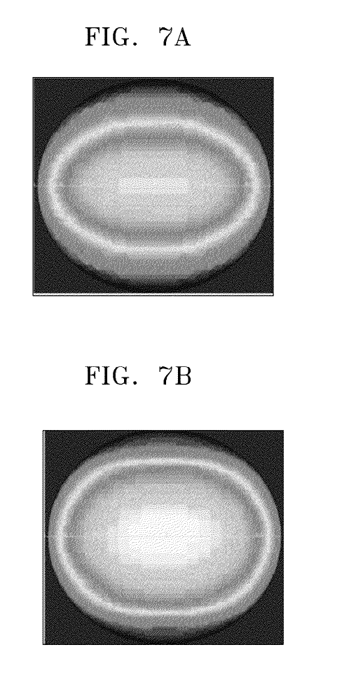

FIG. 6 is a schematic cross-sectional view illustrating an organic light-emitting display apparatus according to a comparative example. FIG. 7A is a simulation image showing the intensity of light emitted from a single pixel of the exemplary embodiment of the organic light-emitting display apparatus described with reference to FIGS. 1 and 2, according to the invention. FIG. 7B is a simulation image showing the intensity of light emitted from a single pixel of the comparative example of the organic light-emitting display apparatus described with reference to FIG. 6. Here, it is denoted that the single pixel includes red color sub-pixel P1, green color sub-pixel P2, and blue color sub-pixel P3.

Referring to FIG. 6, the organic light-emitting display apparatus according to the comparative example includes a substrate 10, an organic light-emitting device 20 disposed on the substrate 10, an encapsulating film 30, and an anti-reflection film 50. However, a first entirely planar layer 41 having a low refractive index and a second entirely planar layer 42 having a high refractive index, of an optical layer 40, are included between the encapsulating film 30 and the anti-reflection film 50, and not a lens unit.

Referring to FIGS. 7A and 7B, it is confirmed that brightness of a central region of the image of FIG. 7B for light emitted from a single pixel of the comparative example of is greater than that of a central region of the image of FIG. 7A for light emitted from a single pixel of the exemplary embodiment of the organic light-emitting display apparatus described with reference to FIGS. 1 and 2. That is, an efficiency of a front surface at the central region of a pixel of the exemplary embodiment of the organic light-emitting display apparatus according to the invention is increased by approximately 15% when compared to that of the comparative example. Also, in regard to an overall light efficiency, the exemplary embodiment shows a light efficiency that is approximately 16.6% greater than the comparative example.

While the invention has been particularly shown and described with reference to exemplary embodiments thereof, it will be understood by those of ordinary skill in the art that various changes in form and details may be made therein without departing from the spirit and scope of the invention as defined by the following claims.

What is claimed is:

1. An organic light-emitting display apparatus comprising:
an organic light-emitting device layer comprising:
a plurality of sub-pixels which emits lights of different colors, and
an organic light-emitting device in each sub-pixel;
an encapsulating film on the organic light-emitting device layer;
a lens layer on the encapsulating film and comprising:
a lens unit corresponding to the each sub-pixel and comprising facing convex surfaces respectively protruding in a light emission direction, and a direction opposite to the light emission direction; and
an anti-anti-reflection film on the lens layer and comprising a color filter corresponding to the each sub-pixel.

2. The organic light-emitting display apparatus of claim 1, wherein the anti-reflection film further comprises a light blocking unit between neighboring sub-pixels.

3. The organic light-emitting display apparatus of claim 2, wherein
the plurality of sub-pixels is arranged in a direction, and
the light blocking unit is separated from the convex surface protruding in the light emission direction among the convex surfaces of the lens unit, by a predetermined gap along the direction in which the plurality of sub-pixels is arranged.

4. The organic light-emitting display apparatus of claim 3, wherein the convex surface protruding in the light emission direction among the convex surfaces of the lens unit has a width smaller than that of the convex surface protruding in a direction opposite to the light emission direction, the widths taken in the direction in which the plurality of sub-pixels is arranged.

5. The organic light-emitting display apparatus of claim 1, wherein the lens layer further comprises:
a first lens sub-layer on the encapsulating film and having a first refractive index; and
a second lens sub-layer on the first lens sub-layer, having a second refractive index, and comprising:
a first convex surface protruding in the light emission direction among the convex surfaces of the lens unit, and
a second convex surface protruding in the direction opposite to the light emission direction among the convex surfaces of the lens unit,
wherein a first surface of the first lens sub-layer contacts the second lens sub-layer and comprises a concave surface corresponding to the second convex surface of the second lens sub-layer.

6. The organic light-emitting display apparatus of claim 5, wherein the second refractive index is greater than the first refractive index.

7. The organic light-emitting display apparatus of claim 6, wherein
the first refractive index is about 1.3 or less, and
the second refractive index is in a range from about 1.7 to about 1.9.

8. The organic light-emitting display apparatus of claim 5, wherein
an imaginary surface extends in a direction in which the plurality of sub-pixels is arranged, and
a first inclination angle formed by the first convex surface at an edge of the first convex surface, with respect to the imaginary surface, is smaller than a second inclination angle formed by the second convex surface at an edge of the second convex surface, with respect to the imaginary surface.

9. The organic light-emitting display apparatus of claim 8, wherein the first inclination angle is in a range from about 15° to about 25°.

10. The organic light-emitting display apparatus of claim 8, wherein the second inclination angle is in a range from about 30° to about 40°.

11. The organic light-emitting display apparatus of claim 1, wherein the convex surface protruding in the direction opposite to the light emission direction among the convex surfaces of the lens unit, comprises:
curved convex surfaces respectively protruding from opposing edges of the convex surface, and
a flat surface between the curved convex surfaces.

12. An organic light-emitting display apparatus comprising:
an organic light-emitting device layer comprising:
a plurality of sub-pixels which emits red, green and blue light, and
an organic light-emitting device in each sub-pixel;
an encapsulating film on the organic light-emitting device layer;
a lens layer on the encapsulating film and comprising:
a first convex surface corresponding to each sub-pixel and protruding in a light emission direction, and
a second convex surface facing the first convex surface and protruding in a direction opposite to the light emission direction; and
an anti-reflection film on the lens layer.

13. The organic light-emitting display apparatus of claim 12, wherein the lens layer further comprises:
a first lens sub-layer on the encapsulating film and having a low refractive index; and
a second lens sub-layer on the first lens sub-layer and having a high refractive index,
wherein the second lens sub-layer comprises the first convex surface protruding in the light emission direction and the second convex surface protruding in the direction opposite to the light emission direction.

14. The organic light-emitting display apparatus of claim 13, wherein a first surface of the first lens sub-layer contacts the second lens sub-layer and comprises a concave surface corresponding to the second convex surface of the second lens sub-layer.

15. The organic light-emitting display apparatus of claim 13, wherein the second convex surface comprises:
curved convex surfaces respectively protruding from opposing edges of the second convex surface, and
a flat surface between the curved convex surface and corresponding to a central region of the each sub-pixel.

16. The organic light-emitting display apparatus of claim 12, wherein the anti-reflection film comprises:
a color filter corresponding to the each sub-pixel; and
a light blocking unit between adjacent sub-pixels.

17. The organic light-emitting display apparatus of claim 16, wherein
the plurality of sub-pixels is arranged in a direction, and
the first convex surface is separated from the light blocking unit along the direction in which the sub-pixels is arranged.

18. The organic light-emitting display apparatus of claim 12, wherein
an imaginary surface extends in a direction in which the plurality of sub-pixels is arranged, and
a first inclination angle formed by the first convex surface at an edge of the first convex surface, with respect to the imaginary surface, has a value different from that of a second inclination angle formed by the second convex surface at an edge of the second convex surface, with respect to the imaginary surface.

19. The organic light-emitting display apparatus of claim 18, wherein the first inclination angle is smaller than the second inclination angle.

20. The organic light-emitting display apparatus of claim 18, wherein
the first inclination angle is in a range from about 15° to about 25°, and
the second inclination angle is in a range from about 30° to about 40°.
